(19) United States
(12) Patent Application Publication
(10) Pub. No.: US 2026/0198101 A1
(43) Pub. Date: Jul. 9, 2026

(54) SOLAR MODULE SYSTEMS AND RELATED METHODS

(71) Applicant: CORNING INCORPORATED, CORNING, NY (US)

(72) Inventors: Oladapo Olalekan Bello, Horseheads, NY (US); Kurt Edward Gerber, Dansville, NY (US); Lisa Lynn Griesbach Hawkins, Corning, NY (US); Eric Scott Hamby, Pittsford, NY (US); Dhananjay Joshi, Rockville, MD (US); James Ernest Webb, Corning, NY (US)

(21) Appl. No.: 19/132,996

(22) PCT Filed: Nov. 29, 2023
(86) PCT No.: PCT/US2023/081508

§ 371 Date: May 27, 2025

Related U.S. Application Data
(60) Provisional application No. 63/429,032, filed on Nov. 30, 2022.

(51) Int. Cl. H10F 19/80; H10F 77/30

(52) U.S. Cl. CPC H10F 19/807; H10F 19/804; H10F 77/315

(57) ABSTRACT

Various embodiments of a solar module and related methods are disclosed herein, including at least one solar cell having a functional material positioned in electrical communication with an electrical wiring component, a first substrate configured of a transparent material; a second substrate, configured in spaced relation from the first substrate, such that the functional material is configured between the first substrate and the second material and an encapsulant (at least one) retained in place via an encapsulant configured between the first substrate and the solar cell and the second substate and the solar cell, further configured to retain the solar cell in place between the first substrate and the second substrate; wherein at least one of the first substrate and the second substrate is a glass material.

### CROSS-REFERENCE TO RELATED APPLICATIONS

This application claims the benefit of priority under 35 U.S.C. § 119 of U.S. Provisional Application No. 63/429,032 filed Nov. 30, 2022, the content of which is incorporated herein by reference in its entirety.

### BACKGROUND

For glass-glass modules, glass selection is typically done without full consideration of how other components in the module (e.g., encapsulants and support structure) work in combination with glass to resist impact and deflection under loading, resulting in heavier, less efficient modules due to thicker glass. Improvements are desired to reduce weight, improve efficiency, and improve performance parameters.

### SUMMARY

With the embodiments set forth herein, a systems approach is embodied to design a tailored solar module with one or more improved properties/advantages including: a lighter weight, more efficient, and higher mechanical reliability solar module. Without being bound by any particular mechanism or theory, the present inventors have designed the solar module stack up to achieve improved performance (e.g., hail impact and wind and snow loading performance/load bearing requirements).

In one aspect, a solar module is provided, comprising: at least one solar cell having a functional material positioned in electrical communication with an electrical wiring component, wherein the functional material of the solar cell is configured to capture photons and convert them to electrons, a first substrate configured of a transparent material; a second substrate, configured in spaced relation from the first substrate, such that the functional material is configured between the first substrate and the second material and an encapsulant (at least one) retained in place via an encapsulant configured between the first substrate and the solar cell and the second substate and the solar cell, further configured to retain the solar cell in place between the first substrate and the second substrate; wherein at least one of the first substrate and the second substrate is a glass material.

In some embodiments, the first substrate and second substrate are selected from borosilicate glass and sodalime glass.

In some embodiments, at least one of the first and second substrates are a flexible glass ribbon (e.g., Willow Glass).

In some embodiments, the first substrate and second substrate have the same thicknesses.

In some embodiments, the first substrate and second substrate have the different thicknesses.

In some embodiments, the first substrate is thicker than the second substrate.

In some embodiments, the first substrate is thinner than the second substrate.

In some embodiments, the encapsulate is selected from optically clear adhesive (OCA), adhesive, a polymeric interlayer, an ionomer, and/or combinations thereof.

In some embodiments, the solar module further comprises: an electrical connection, configured to receive and transmit electrons from the solar cell to a junction box.

In some embodiments, the solar module further comprises: a seal, configured to sealingly engage the at least one solar module (i.e., protect functional material and/or solar cell from humidity, water, air, reactive components).

In some embodiments, the second substrate is configured of a transparent, translucent, or opaque materials.

In some embodiments, at least one of the first and second substrates are a polymer or resin material.

In some embodiments, the module comprises a frame and gasket configured to sealingly engage the solar module.

In some embodiments, the solar module is configured as a solar panel (e.g., having a gasket, frame, electrical wiring, junction box).

In some embodiments, the solar module includes an anti-reflective coating on a first surface of the first substrate.

In some embodiments, the electrical connection is configured to transmit the electrons form the solar cell to a junction box or a battery.

In some embodiments, the interlayer is selected from the group consisting of a polyvinyl butyral (PVB), an acoustic PVB (APVB), an ionomer, an ethylene-vinyl acetate (EVA), a thermoplastic polyurethane (TPU), a polyester (PE), a polyethylene terephthalate (PET), and combinations thereof, and wherein the interlayer has a thickness in a range from 0.5 mm to 2.5 mm.

More specifically, the components of the stack-up, including the front glass and back glass (thicknesses and properties); encapsulant(s)/interlayer(s); lamination process/method; and support structure (frame and/or mounting); microbending performance (e.g., through electrical connector design coupled with encapsulant(s) selection); and through design of the support structure and 2D bending of the laminated stack.

### BRIEF DESCRIPTION OF THE DRAWINGS

The accompanying drawings are included to provide a further understanding and are incorporated in and constitute a part of this specification. The drawings illustrate one or more embodiment(s), and together with the description serve to explain principles and operation of the various embodiments. In the drawings:

FIG. 1 provides a schematic cut-away side view of an embodiment of a solar panel having one or more features set forth herein, in conjunction with one or more aspects of the present disclosure.

FIG. 2 provide a flow diagram which illustrates the various performance requirements (governed by impact and load requirements imposed by IEC standards) design considerations of various solar module components, and potential outcomes of the embodied solar module.

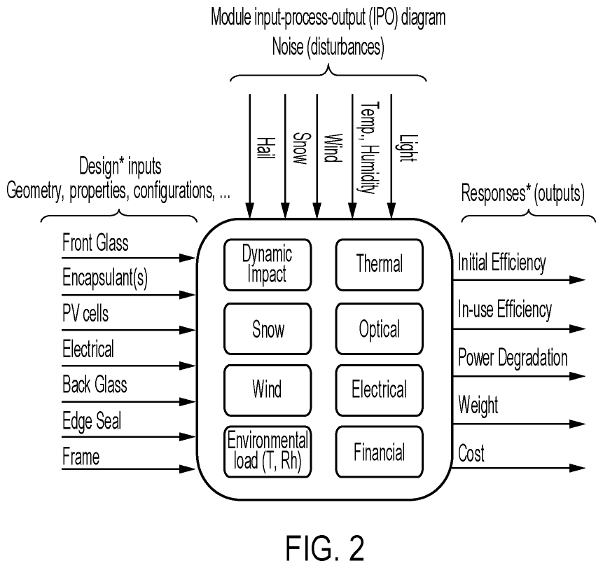

FIG. 3 is a schematic cut-away side view of an embodiment of a solar module incorporating a frame, where the environmental affects are depicted, including hail strike, wind/snow load, module response (e.g., deflection) and transmissivity required for an effective solar module, in accordance with one or more aspects of the present disclosure.

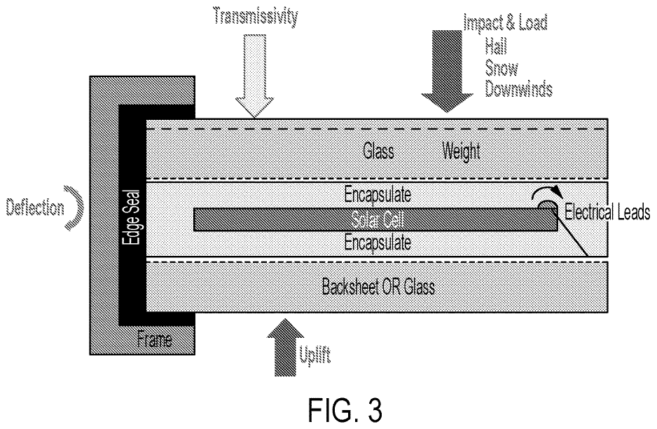

FIG. 4 is a schematic cut-away side view of an embodiment of a solar module incorporating support rails with an adhesive material, in accordance with one or more aspects of the present disclosure.

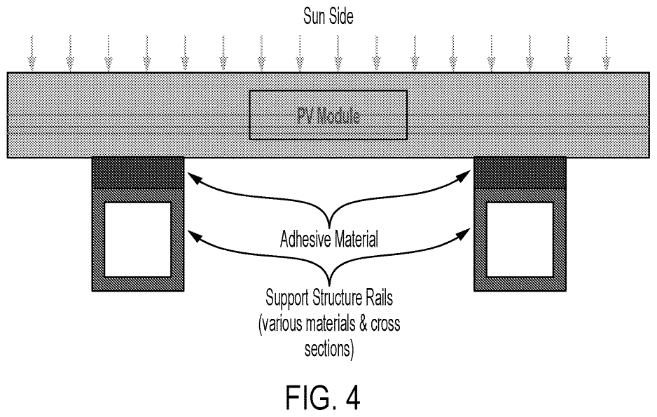

FIGS. 5A through 5C depict three different embodiments of support structures for the solar module, in accordance with various aspects of the present disclosure.

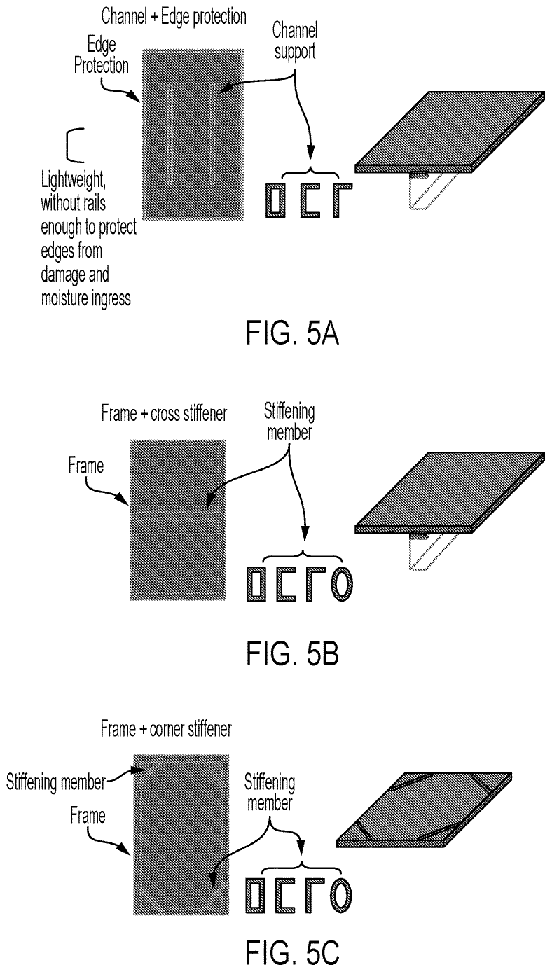

FIG. 6 provides some aspects and features of incorporating edge protection into the solar module, in accordance with various aspects of the present disclosure.

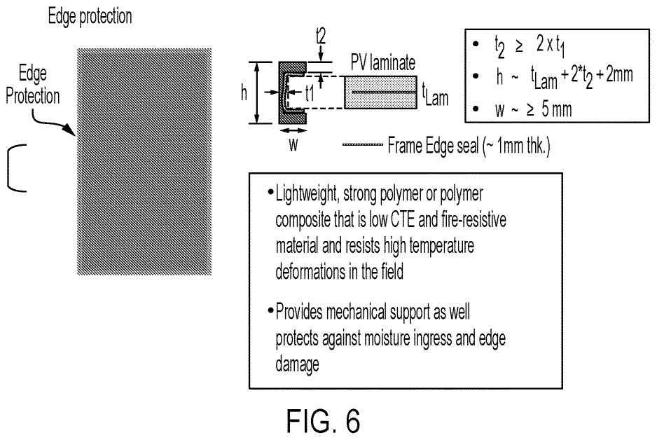

FIG. 7 depicts a non-planar configuration of the solar module, retained via a frame, or wired members, in accordance with one or more aspects of the present disclosure.

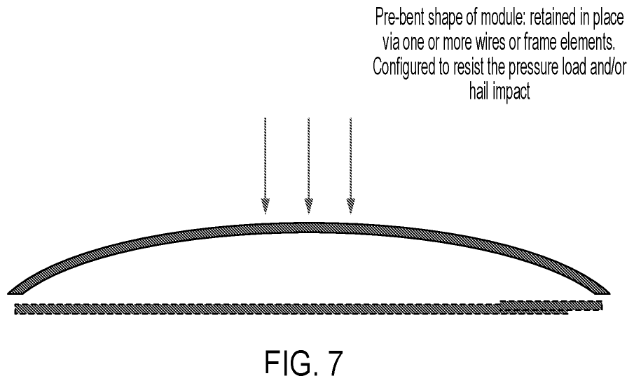

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary and are intended to provide an overview or framework to understanding the nature and character of the claims.

### DETAILED DESCRIPTION

The disclosure relates to a various embodiments of a glass-glass solar module embodiments having advantageous properties, including improved efficiency, reliability, and/or lower weight.

Various embodiments are disclosed herein to improve hail impact resistance, micro-bending performance, wind and snow load performance and weight reduction (light weighting). Set forth below, one or more of these aspects are incorporated into solar module embodiments herein.

Various embodiments believed to improve hail impact resistance include, individually or in combination, the embodied features below.

In some embodiments, multiple encapsulant layers are utilized in the laminated stack, where each encapsulant layer may be different.

In some embodiments, multiple encapsulant types in each “encapsulant layer,” where encapsulant types within the layer are determined by position relative to other components in the laminated stack.

As one non-limiting example, a stiffer encapsulant is located at the at perimeter for shear transfer between glass panels and less stiff encapsulant is located in interior to maintain spacing. As used herein, stiffer means higher young's modulus of elasticity, while less stiff means lower young's modulus of elasticity.

In some embodiments, an encapsulant layer(s) where the material properties of the encapsulant are spatially dependent.

In some embodiments, various combinations of glass treatments (heat strengthening, tempering), compositions (chemically strengthened) and thicknesses are utilized to promote compressive stress/depth of layer.

In some embodiments, a composite encapsulant is utilized to modify thermal mechanical properties-high modulus and low CTE (glass particle filling)-could contribute to improved microbending and general stiffness of the solar module.

In some embodiments, edge seal is incorporated with or without a surrounding frame.

In some embodiments, different glass edge process technologies are utilized (fire polishing, grind & etching) on the first substrate vs. the second substrate.

In some embodiments, “dampening” adhesives are incorporated into the support structure and/or the mount between the PV module and the support structure.

Various embodiments believed to improve micro-bending performance include, individually or in combination, the embodied features below.

In some embodiments, glass properties (thickness, modules, fracture resistance) are tailored based on the required performance of the solar module (e.g., middle of module is different than edges where frame and/or wiring (but no cell) could be located).

In some embodiments, an encapsulant layer(s) is incorporated, where the material properties of the encapsulant are spatially dependent based on the position within the module (e.g., over the solar cell, under the solar cell, adjacent to the solar cell, proximal to an outer edge of the solar module).

In some embodiments, low thickness electrical features are utilized, to minimize localized bending and/or stresses in the substrates, which can contribute to crack initiation and/or or crack propagation. In some embodiments, in order to reduce the profile height (thickness) of the electrical features/wiring, various deposition processes are utilized, including additive manufacturing and printing/deposition techniques.

Various embodiments believed to improve wind and snow loading performance include, individually or in combination are embodied below.

In some embodiments, both frame and rail design are incorporated into the solar module/panel to promote improved mechanical reliability.

In some embodiments, the solar module (or the upper or lower substrates) are configured with a two-dimensional bend (e.g., curved laminated stack) for added stiffness and for improved hail performance.

In some embodiments, glass properties (thickness, modules, fracture resistance) of front & back glass are tailored to achieve performance of laminated system including laminate designs with different thickness of front and back to achieve improved bending of the solar module.

In some embodiments, lamination process/methods are utilized to achieve a two-dimensional bending.

In some embodiments, the frame and/or mounting (support structure) is configured to achieve improved two-dimensional bending.

In some embodiments, 360° tensioning of at least one of the glass substrates is provided for improved stiffness and/or hail performance (e.g., drumhead or trampoline concept).

In some embodiments, structural adhesives are positioned within a portion of a region of the stack in order to promote/improve two-dimensional bending and 360° tensioning, for improved load and/or hail strike performance.

Various embodiments believed to improve the module weight (weight reduction) include, individually or in combination are embodied below.

In some embodiments, different glass edge process technologies are included for at least one of the first substrate and second substrate (e.g., fire polishing, grind & etching).

In some embodiments, module edge protection is utilized, by configuring the edge with softer polymer materials. By utilizing such softer polymer materials, the frame may be omitted from the solar module (e.g., impacting overall weight of the unit).

In some embodiments, the module is configured (e.g., on at least one major surface) with support structure rails, which are configured to reduce of panel deflection.

### Glass Substrate:

Glass substrate properties include, but are not limited to: composition, cross-sectional thickness, coefficient of thermal expansion, forming method, surface roughness, edge profile, strengthened or unstrengthened, to name several.

In some embodiments, the first substrate and second substrate have the same properties.

In some embodiments, the first substrate and second substrates differ in at least one of: composition, cross-sectional thickness, coefficient of thermal expansion, forming method, surface roughness, edge profile, strengthening.

In some embodiments, the first substrate and second substrates differ in at least two of: composition, cross-sectional thickness, coefficient of thermal expansion, forming method, surface roughness, edge profile, strengthening.

In some embodiments, the first substrate and second substrates differ in at least three of: composition, cross-sectional thickness, coefficient of thermal expansion, forming method, surface roughness, edge profile, strengthening.

In some embodiments, the first substrate and second substrates differ in at least four of: composition, cross-sectional thickness, coefficient of thermal expansion, forming method, surface roughness, edge profile, strengthening.

In some embodiments, the first substrate and second substrates differ in at least five of: composition, cross-sectional thickness, coefficient of thermal expansion, forming method, surface roughness, edge profile, strengthening.

In some embodiments, the first substrate and second substrates differ in at least six of: composition, cross-sectional thickness, coefficient of thermal expansion, forming method, surface roughness, edge profile, strengthening.

In some embodiments, the first substrate and second substrates differ in all of: composition, cross-sectional thickness, coefficient of thermal expansion, forming method, surface roughness, edge profile, strengthening.

In some embodiments, the first substrate and second substrates differ in type of strengthening. In some embodiments, the first substrate and second substrates differ in that one is strengthened, and one is not strengthened.

Glass composition/type:

The first substrate and second substrate are selected from sodalime glass, a boro-aluminosilicate glass, an alkaline earth boro-aluminosilicate glass, or an alkali-free boro-aluminosilicate glass. Exemplary commercial glass products include, but are not limited to, Corning® EAGLE XG® and Lotus™ NXT glasses.

### Glass Forming Method:

In some embodiments, the first substrate or second substrate is a float product, a rolled product, or fusion draw product.

### Glass Surface Roughness

In one or more embodiments, the first glass substrate or second glass substrate may be provided with a functional surface. In some embodiments, the functional surface is a micropatterning to create a surface pattern which acts as an anti-reflective coating.

### Edge Profile:

In some embodiments, at least one of the first substrate and second substrate have an edge finish/edge profile. Some non-limiting examples of edge profiles include fire polishing, grinding, and etching.

### Thickness:

In embodiments, the substrate thickness is at least 0.5 mm, at least 1 mm, at least 2 mm, at least 3 mm, at least 3.3 mm, or at least 3.8 mm.

In one or more embodiments, the substrate thickness is in a range from about 0.1 mm to about 6 mm, 0.2 mm to about 6 mm, 0.3 mm to about 6 mm, 0.4 mm to about 6 mm, 0.5 mm to about 6 mm, 0.6 mm to about 6 mm, 0.7 mm to about 6 mm, 0.8 mm to about 6 mm, 0.9 mm to about 6 mm, 1 mm to about 6 mm, 1.1 mm to about 6 mm, 1.2 mm to about 6 mm, 1.3 mm to about 6 mm, 1.4 mm to about 6 mm, 1.5 mm to about 6 mm, 1.6 mm to about 6 mm, from about 1.8 mm to about 6 mm, from about 2 mm to about 6 mm, from about 2.2 mm to about 6 mm, from about 2.4 mm to about 6 mm, from about 2.6 mm to about 6 mm, from about 2.8 mm to about 6 mm, from about 3 mm to about 6 mm, from about 3.1 mm to about 6 mm, from about 3.2 mm to about 6 mm, from about 3.3 mm to about 6 mm, from about 3.4 mm to about 6 mm, from about 3.5 mm to about 6 mm, from about 3.6 mm to about 6 mm, from about 3.7 mm to about 6 mm, from about 3.8 mm to about 6 mm, from about 3.9 mm to about 6 mm, from about 4 mm to about 6 mm, from about 4.2 mm to about 6 mm, from about 4.4 mm to about 6 mm, from about 4.5 mm to about 6 mm, from about 4.6 mm to about 6 mm, from about 4.8 mm to about 6 mm, from about 5 mm to about 6 mm, from about 5.2 mm to about 6 mm, from about 5.4 mm to about 6 mm, from about 5.5 mm to about 6 mm, from about 5.6 mm to about 6 mm, from about 5.8 mm to about 6 mm, from about 1.6 mm to about 5.8 mm, from about 1.6 mm to about 5.6 mm, from about 1.6 mm to about 5.5 mm, from about 1.6 mm to about 5.4 mm, from about 1.6 mm to about 5.2 mm, from about 1.6 mm to about 5 mm, from about 1.6 mm to about 4.8 mm, from about 1.6 mm to about 4.6 mm, from about 1.6 mm to about 4.4 mm, from about 1.6 mm to about 4.2 mm, from about 1.6 mm to about 4 mm, from about 1.6 mm to about 3.9 mm, from about 1.6 mm to about 3.8 mm, from about 1.6 mm to about 3.7 mm, from about 1.6 mm to about 3.6 mm, from about 1.6 mm to about 3.5 mm, from about 1.6 mm to about 3.4 mm, from about 1.6 mm to about 3.3 mm, from about 1.6 mm to about 3.2 mm, from about 1.6 mm to about 3.1 mm, from about 1.6 mm to about 3 mm, from about 1.6 mm to about 2.8 mm, from about 1.6 mm to about 2.6 mm, from about 1.6 mm to about 2.4 mm, from about 1.6 mm to about 2.2 mm, from about 1.6 mm to about 2 mm, from about 1.6 mm to about 1.8 mm, from about 3 mm to about 5 mm, or from about 3 mm to about 4 mm.

### Strengthened or Unstrengthened

Further, in embodiments, the first glass substrate and/or the second glass substrate may be strengthened. As some non-limiting examples, strengthening methods include may be thermally, chemically and/or mechanically strengthened. As some non-limiting examples, chemically strengthening includes an ion-exchange treatment.

As some non-limiting examples, mechanically strengthening includes utilizing a mismatch of the coefficient of thermal expansion between portions of the solar module (glass portions) to create a compressive stress region and a central region exhibiting a tensile stress. As some non-limiting examples, strengthening is completed by thermal methods, e.g., heating the glass to a temperature above the glass transition point and then rapidly quenching.

In some embodiments, various combinations of chemical, mechanical and thermal strengthening may be used to strengthen the glass. In one or more embodiments, one glass substrate is strengthened while the other glass substrate is unstrengthened (but may optionally be annealed.

### CTE

The linear coefficient of thermal expansion (CTE) as referenced herein is measured using ASTM standard E831, “Standard Test Method for Linear Thermal Expansion of Solid Materials by Thermomechanical Analysis,” ASTM E228, “Test Method for Linear Thermal Expansion of Solid Materials with a Push-Rod Dilatometer”, or equivalent. As referenced herein, the coefficient of thermal expansion set forth herein are quantified as a coefficient of thermal expansion (CTE) is measured over a temperature range 0-300° C.

The CTE of a substrate is less than 70×10⁻⁷/° C. and greater than zero as measured over a range of from 0 to about 300 10° C. In some embodiments, the CTE of a substrate is less than 50×10⁻⁷/° C. and greater than zero as measured over a range of from 0 to about 300 degrees C. In some embodiments, the CTE of a substrate is less than about 35×10⁻⁷/° C. and greater than zero, as measured over a range of from 0 to about 300 degrees C.

Soda lime glass has a CTE of approximately 90×10⁻⁷/° C. By comparison, Corning EAGLE XG glass has a CTE of approximately 32×10⁻⁷/° C., which is approximately ⅓ (“one-third”) of the CTE of soda lime glass, as measured over a range of from 0 to about 300° C.

In some embodiments, the first substrate is a high CTE glass, and the second substrate is a low CTE glass. In some embodiments, the first substrate is a low CTE glass, and the second substrate is a high CTE glass. In some embodiments, both the first and second substrates are high CTE glasses but have different CTEs. In some embodiments, both first and second substrates are low CTE glasses, but have different substrates. In some embodiments, the first and second substrates have the same CTE. As a non-limiting example, a high CTE glass is greater than 50×10⁻⁷/° C., while a low CTE glass is less than 50×10⁻⁷/° C.

### Interlayer/Encapsulant

In one or more embodiments, the encapsulant (also called an interlayer) bonds the components and/or layers of the solar module together.

### Composition:

In some embodiments, the interlayer comprises a polymer, such as at least one of polyvinyl butyral (PVB), acoustic PVB (APVB), an ionomer, an ethylene-vinyl acetate (EVA) and a thermoplastic polyurethane (TPU), a polyester (PE), a polyethylene terephthalate (PET), or the like.

### Thickness:

The thickness of the encapsulant may be in the range from about 0.5 mm to about 2.5 mm, in particular from about 0.7 mm to about 1.5 mm. In other embodiments the thickness may be less than 0.5 mm or more than 2.5 mm.

In instances where there are two encapsulant layers, the encapsulant layers can have the same thickness, or different thicknesses. In some embodiments, the first encapsulant layer is thicker than the second encapsulant layer. In some embodiments, the second encapsulant layer is thicker than the first encapsulant layer.

### Layers/Composite:

In some embodiments, an encapsulant layer is a single material. In some embodiments, an encapsulant layer is a composed of multiple layers, in a composite interlayer, with two distinct layers, three distinct layers, or more distinct layers. In one embodiment, the encapsulant is in a sandwich configuration, with one layer surrounded by two other layers on each of its major surfaces, the two ‘outer’ layers being of the same material. In some embodiments, the interlayer has distinct regions of one interlayer vs. a composite interlayer, depending on the position relative to the solar cell in the solar module and/or the position relative to the edge of the stack up of the solar module.

In some embodiments, multiple polymeric layers or films providing various functionalities to the laminate structure and/or the PV module. For example, the interlayer may incorporate at least one of: solar insulation, sound dampening, an antenna or electrical wiring/bus work for the solar cell, an anti-glare treatment, or an anti-reflective treatment, among others.

### Coatings:

In one or more embodiments, the first glass substrate or second glass substrate may be provided with a coating.

In embodiments, the coating is an anti-reflective coating. In particular embodiments, the anti-reflective coating is applied to the one or more surfaces of the first glass substrate and the second glass substrate. In some embodiments, the anti-reflective coating is applied to the outermost surfaces of the solar module (e.g., the upper and lower surfaces). In embodiments, the anti-reflective coating comprises multiple layers of low and high index materials or low, medium, and high index materials. For example, in embodiments, the anti-reflective coating includes from two to twelve layers of alternating low and high index materials, such as silica (low index) and niobia (high index).

In general, anti-reflective coatings having more layers in the stack will perform better at higher angles of incidence than anti-reflective coatings having less layers in the stack. For example, at an angle of incidence of, e.g., greater than 60°, an anti-reflective coating stack having four layers will perform better (less reflection) than an anti-reflective coating stack having two layers. Further, in embodiments, an anti-reflective coating stack having an ultra low index material will perform better (less reflection) than an anti-reflective coating stack having a low index material.

### Module:

Ratio of substrate thicknesses:

In one or more embodiments the second glass substrate is relatively thin in comparison to the first substrate. In other words, the first glass substrate has a thickness greater than the second glass substrate.

In such embodiments, first substrate thickness and the second substrate thickness differ from one another. For example, the first thickness is about 2.0 mm or greater, about 2.1 mm or greater, about 2.2 mm or greater, about 2.3 mm or greater, about 2.4 mm or greater, about 2.5 mm or greater, about 2.6 mm or greater, about 2.7 mm or greater, about 2.8 mm or greater, about 2.9 mm or greater, about 3.0 mm or greater, about 3.1 mm or greater, about 3.2 mm or greater, about 3.3 mm or greater, 3.4 mm or greater, 3.5 mm or greater, 3.6 mm or greater, 3.7 mm or greater, 3.8 mm or greater, 3.9 mm or greater, 4 mm or greater, 4.2 mm or greater, 4.4 mm or greater, 4.6 mm or greater, 4.8 mm or greater, 5 mm or greater, 5.2 mm or greater, 5.4 mm or greater, 5.6 mm or greater, 5.8 mm or greater, or 6 mm or greater. In some embodiments the first thickness is in a range from about 2.0 mm to about 6 mm, from about 2.1 mm to about 6 mm, from about 2.2 mm to about 6 mm, from about 2.3 mm to about 6 mm, from about 2.4 mm to about 6 mm, from about 2.5 mm to about 6 mm, from about 2.6 mm to about 6 mm, from about 2.8 mm to about 6 mm, from about 3 mm to about 6 mm, from about 3.2 mm to about 6 mm, from about 3.4 mm to about 6 mm, from about 3.6 mm to about 6 mm, from about 3.8 mm to about 6 mm, from about 4 mm to about 6 mm, from about 2.0 mm to about 5.8 mm, from about 2.0 mm to about 5.6 mm, from about 2.0 mm to about 5.5 mm, from about 2.0 mm to about 5.4 mm, from about 2.0 mm to about 5.2 mm, from about 2.0 mm to about 5 mm, from about 2.0 mm to about 4.8 mm, from about 2.0 mm to about 4.6 mm, from about 2.0 mm to about 4.4 mm, from about 2.0 mm to about 4.2 mm, from about 2.0 mm to about 4 mm, from about 2.0 mm to about 3.8 mm, from about 2.0 mm to about 3.6 mm, from about 2.0 mm to about 3.4 mm, from about 2.0 mm to about 3.2 mm, or from about 2.0 mm to about 3 mm.

In one or more embodiments, either one of or both the first length and the first width is about 0.25 meters (m) or greater. For example, the first length and/or the second length may be in a range from about 1 m to about 3 m, from about 1.2 m to about 3 m, from about 1.4 m to about 3 m, from about 1.5 m to about 3 m, from about 1.6 m to about 3 m, from about 1.8 m to about 3 m, from about 2 m to about 3 m, from about 1 m to about 2.8 m, from about 1 m to about 2.8 m, from about 1 m to about 2.8 m, from about 1 m to about 2.8 m, from about 1 m to about 2.6 m, from about 1 m to about 2.5 m, from about 1 m to about 2.4 m, from about 1 m to about 2.2 m, from about 1 m to about 2 m, from about 1 m to about 1.8 m, from about 1 m to about 1.6 m, from about 1 m to about 1.5 m, from about 1.2 m to about 1.8 m or from about 1.4 m to about 1.6 m.

For example, the first width and/or the second width may be in a range from about 0.5 m to about 2 m, from about 0.6 m to about 2 m, from about 0.8 m to about 2 m, from about 1 m to about 2 m, from about 1.2 m to about 2 m, from about 1.4 m to about 2 m, from about 1.5 m to about 2 m, from about 0.5 m to about 1.8 m, from about 0.5 m to about 1.6 m, from about 0.5 m to about 1.5 m, from about 0.5 m to about 1.4 m, from about 0.5 m to about 1.2 m, from about 0.5 m to about 1 m, from about 0.5 m to about 0.8 m, from about 0.75 m to about 1.5 m, from about 0.75 m to about 1.25 m, or from about 0.8 m to about 1.2 m.

In some embodiments, the weight of the solar module is less than 10 kg/m², or less than 12 kg/m²; or less than 14 kg/m²; or less than 16 kg/m²; or less than 18 kg/m². In some embodiments, the weight of the solar module is less than 5 kg/m², or less than 7 kg/m²; or less than 8 kg/m².

One or more embodied solar modules set forth herein are configured to pass the following tests: IEC 61215:2016 & 61730-1:20165, CE; IEC 61701 Salt Mist Corrosion; IEC 60068-2-68 Dust and Sand Resistance; IEC 63209-1 Extended Stress Test; Long-Term Sequential Thresher Test; and/or PID Resistant.

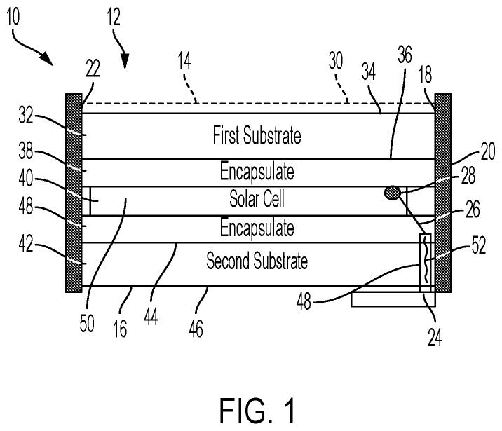

FIG. 1 provides a schematic cut-away side view of an embodiment of a solar panel 10 having one or more substrates from the borosilicate compositions set forth herein, in conjunction with various aspects of the present disclosure.

Referring to FIG. 1, the solar cell 40 is retained between two substrates, a first substrate 32 and a second substrate 42. An encapsulant 38 (e.g., first encapsulant) is configured between the solar cell 40 and the second surface 36 of the first substrate 32. An encapsulant 48 (e.g., a second encapsulant or an integral layer/monolith with the encapsulant 38) is configured between the first surface 44 of the second substrate and the solar 40. In this configuration, the solar cell 40 is attached to the first substrate 32 and second substrate 42.

The solar cell 40 is configured with a functional material 50, which converts photons into electrons (the functional part of the solar cell). The solar cell 40 is configured from functional material 50, electrode/electrode layers, transparent oxide layers, and/or additives or interlayers to configure the solar cell 40. This layup, along with the edge seal 22, provides an embodiment of a solar module 12. The solar panel 10 of FIG. 18 incorporates a frame 20 (e.g., in perimetrical configuration around the outer edge of the solar module 12 (e.g., at least partially overlapping with the edge seal 22 of the solar module 12). The frame optionally includes a gasket, which is configured between the frame 20 body and an outer edge of the solar module 12. Optionally, a coating (e.g., anti-reflective coating) is applied to the first surface 34 of the first substrate 32 (and/or the second surface 45 of the second substrate 42 (not shown)).

The solar cell 40 is configured with electrical leads that connect the solar cell to the electrical wiring and/or junction box, such that the solar cell is in electrical communication with the j-box and can transmit electrons in the form of electricity/electrical current out of the solar cell 40.

In some embodiment, the leads and electrical wires/contacts are configured within the frame 20 edge, between the edge seal 22 and the frame/gasket assembly.

In some embodiments, the leads and electrical wires are configured to extend through at least a portion of the second substrate (e.g., through a hole or discontinuous edge portion) such that the electrical wiring is directed through a major surface portion of the second substrate and out of the solar panel into the junction box 24.

As shown, the first substrate can be configured as the major surface facing the sun/photon capture. The solar panel 10 or module 12 can also be configured in a bifacial configuration, such that photon capture is configured through the first substrate 32 and the second substrate 42.

As a non-limiting embodiment, the encapsulant may be configured as a sealant, glue, adhesive, room temperature curing polymer, UV curing polymer, an adhesive, an optically clear adhesive, and/or combinations thereof. In some embodiments, by incorporating the retrofit cover onto the surface of a solar panel (e.g., installed), the upper-most surface of the solar panel can be tailored for one or more advantages of the embodied borosilicate compositions of the present invention, as set forth herein.

In some embodiments, an anti-reflective coating is applied to the first surface of the first substrate in order to reduce the reflection on the surface of the glass coating, thereby increasing efficiency of the solar panel. In some embodiments, the AR coating is configured to get more photons into the solar cell.

In some embodiments, the solar module is a frameless module. When the solar module is a frameless module, an edge seal is configured perimetrically around the solar stack to protect the electrical and functional materials components from environmental impact (e.g., water, oxygen, dust, humidity).

In some embodiments, the solar module is configured with a frame. In some embodiments, the solar module includes an edge seal configured around the perimetrical edge of the solar stack.

In some embodiments, the frame cooperates with a gasket to provide sealing engagement around the perimetrical edge of the solar module and/or to provide compressive retention of the stack components.

In some embodiments, a frit or a metal is utilized between the first substrate and the second substrate, where the frit is laser bonded to create an edge seal.

In some embodiments, the encapsulate is an interlayer which is laminated with the first substrate, second substrate, and solar cell to form a solar module.

In some embodiments, the encapsulate is an EVA, polyolefin, or the like material. In some embodiments, the encapsulate is a polymer configured to protect the solar cell from water egress and/or provide a modulus of elasticity to prevent cracking of the first and/or second substrate. In some embodiments, the encapsulant attributes (thickness, modulus of elasticity) are tailored based on the glass strength, to design a solar panel that withstands impact and load forces required in service.

In some embodiments, the first surface of the first substrate is configured with a textured coating. The textured coating is configured to promote photons to be directed through the first glass substrate and into the solar cell. In one or more embodiments as set forth herein, the texture for the front coating can be tailored for efficiency improvement.

In some embodiments, the coating on the back glass can be configured to provide an index match to the second encapsulant such that improved adhesion is provided.

In some embodiments, the borosilicate compositions described herein provide crack arresting features upon receiving a crack initiating force, such that the crack is reduced, prevented, and/or eliminated from propagating and damaging the solar panel.

In some embodiments, the solar panel passes a hail impact test of 2-4 J.

In some embodiments, the solar panel passes a load test sufficient to withstand snow loads, wind updraft and downdraft, and other environmental evaluations for solar panels and/or solar installations.

In some embodiments, the solar panel is tailored with the appropriate design features and materials to enable continued performance through upwinds, downwinds, excessive temperatures, and/or deflections caused by the aforementioned environmental conditions.

In some embodiments, the stack is 3 to 4 mm thick.

In some embodiments, the stack is symmetrical.

In some embodiments, the stack is asymmetrical.

In some embodiments the solar panel or solar module described in FIG. 18 and 19A-C is configured with additional substrates on the first surface or second surface (with accompanying encapsulants) to further protect the solar module.

In some embodiments, the first substrate and second substrate are configured to promote at least one of the following attributes: protect the solar cell from impact, flaws and bending, minimize optical loss, manage surface attributes, among other items.

In some embodiments, the solar panel is configured as bifacial (captures photons from the back/second substrate of the solar module).

In some embodiments, the solar panel is a tandem design (with multiple solar cells stacked in a panel).

In some embodiments, the glass compressive stresses are tailored (e.g., configured in compression) to reduce, prevent, and/or eliminate crack and/or flaw migration.

In some embodiments, the solar cell is selected from: silicon, semiconductor compounds, and emerging market material categories. In some embodiments, silicon solar cell includes a crystalline (e.g., single crystalline or multi-crystalline) or amorphous (hydrogenated amorphous silicon) solar cell. In some embodiments, semiconductor compounds include chalcogenides (e.g., cadmium telluride, copper zinc tin sulphide, copper indium gallium diselenide) or compounds of Group III-V (e.g., gallium indium phosphorus, gallium arsenide, to name a few). In some embodiments, the solar materials are emerging market material categories including dye sensitized solar cells, colloidal quantum dot, perovskite, or organic materials) In one or more embodiments described herein, the solar module and/or solar panel is configured to pass: IEC-type testing for dynamic loading, static loading, and/or thermal cycling.

In one or more embodiments as described herein, the solar module and/or solar panel is configured to pass at least one of: IEC 61216 Module Quality Tests (MQT) for UV preconditioning (MQT 10), thermal cycling (MQT 11), humidity-freeze (MQT 12), damp heat (MQT 13), potential induced degradation (MQT 21), and perovskite stability testing covering thermal, irradiance, electrical, and environmental protocols (PACT protocol as described by IEC as of the date of this application), and/or combinations thereof. In some embodiments, the solar module and/or solar panel is configured to pass: IEC 61216 Module Quality Tests (MQT) for UV preconditioning (MQT 10), thermal cycling (MQT 11), humidity-freeze (MQT 12), damp heat (MQT 13), potential induced degradation (MQT 21), and perovskite stability testing covering thermal, irradiance, electrical, and environmental protocols (PACT protocol as described by IEC as of the date of this application).

### REFERENCE NUMBERS

Solar panel 10
Solar module 12
First surface 14
Second surface 16
Edge 18
Frame 20
Edge seal 22
J-box 24
Electrical connection 26
Electrical leads 28
Coating (e.g., AR coating/anti-reflective coating) 30
First substrate 32
First surface of first substrate 34
Second surface of first substrate 36
First encapsulate (interlayer) 38
Solar cell 40, 40′
Second encapsulate 48
Second substrate 42
First side of second substrate 44
Second side of second substrate 46
Hole for leads 48
Functional material 50
Electrodes 52
Retrofit cover 54
Third encapsulate 56

What is claimed is:

1. A solar module, comprising:
a. at least one solar cell having a functional material positioned in electrical communication with an electrical wiring component, wherein the functional material of the solar cell is configured to capture photons and convert them to electrons, b. a first substrate configured of a transparent material;
c. a second substrate, configured in spaced relation from the first substrate, such that the functional material is configured between the first substrate and the second material and
d. an encapsulant configured between the first substrate and the solar cell and the second substate and the solar cell, further configured to retain the solar cell in place between the first substrate and the second substrate;
e. wherein at least one of the first substrate and the second substrate is a glass material, further wherein, the first substrate and the second substrate are configured to differ in at least five properties selected from the group consisting of: composition; cross-sectional thickness; coefficient of thermal expansion, forming method, surface roughness, edge profile, and strengthening.

2. The solar module of claim 1, wherein the first substrate and second substrate are selected from borosilicate glass and sodalime glass.

3. The solar module of claim 1, wherein at least one of the first and second substrates are a flexible glass ribbon.

4. The solar module of claim 1, wherein the first substrate and second substrate have the same thicknesses.

5. The solar module of claim 1, wherein the first substrate and second substrate have the different thicknesses, such that the first substrate is thicker than the second substrate, or such that the first substrate is thinner than the second substrate.

6. The solar module of claim 1, wherein the first substrate has a thickness of between 2 mm to 6 mm.

7. The solar module of claim 1, wherein the solar cell, first substrate, second substrate, and encapsulate are configured to provide a stack, such that the stack is configured with a cross-sectional thickness of not greater than 3mm to 4 mm.

8. The solar module of claim 1, wherein the encapsulate is selected from EVA, polyolefin, optically clear adhesive (OCA), adhesive, a polymeric interlayer, an ionomer, polyvinyl butyral (PVB), an acoustic PVB (APVB), an ionomer, an ethylene-vinyl acetate (EVA), a thermoplastic polyurethane (TPU), a polyester (PE), a polyethylene terephthalate (PET), and combinations thereof; and wherein the encapsulate has a thickness in a range from 0.5 mm to 2.5 mm.

9. The solar module of claim 1, further comprising: an electrical connection, configured to receive and transmit electrons from the solar cell to a junction box.

10. The solar module of claim 1, further comprising: a seal, configured to sealingly engage the at least one solar module.

11. The solar module of claim 1, wherein the second substrate is configured of a transparent, translucent, or opaque materials.

12. The solar module of claim 1, wherein at least one of the first substrate and second substrates are a polymer or resin material.

13. The solar module of claim 1, wherein the module comprises a frame and gasket configured to sealingly engage the solar module.

14. The solar module of claim 1, further configured as a solar panel, wherein the solar panel is configured to have a weight of less than 18 kg/m².

15. The solar module of claim 1, further comprising an anti-reflective coating on a first surface of the first substrate.

16. The solar module of claim 1, wherein the electrical connection is configured to transmit the electrons from the solar cell to a junction box or a battery.

17. The solar module of claim 1, wherein the encapsulate comprises a first encapsulate layer and a second encapsulate layer configured as a monolithic, integral layer between the first substrate, the solar cell, and the second substrate of the solar module.
